(19) United States
(12) Patent Application Publication
(10) Pub. No.: US 2025/0221021 A1
(43) Pub. Date: Jul. 3, 2025

(54) INTEGRATED CIRCUIT DEVICE

(71) Applicant: SAMSUNG ELECTRONICS CO., LTD., Suwon-si (KR)

(72) Inventors: Yeonghan Gwon, Suwon-si (KR); Hanyoung Song, Suwon-si (KR); Jeonghyeon Lee, Suwon-si (KR); Junyoup Lee, Suwon-si (KR); Hakjong Lee, Suwon-si (KR)

(21) Appl. No.: 18/931,838

(22) Filed: Oct. 30, 2024

(30) Foreign Application Priority Data
Dec. 28, 2023 (KR) 10-2023-0195356

(51) Int. Cl. H01L 27/088; H01L 21/762; H01L 21/8234; H01L 29/06; H01L 29/423; H01L 29/775; H01L 29/786

(52) U.S. Cl. CPC H10D 84/83; H10D 30/43; H10D 30/6735; H10D 30/6757; H10D 62/121; H01L 21/76232; H10D 84/0151; H10D 84/038

(57) ABSTRACT

An integrated circuit device includes a gate isolation insulator between the fin-type active regions, the gate isolation insulator cutting and separating at least one gate line among the plurality of gate lines. The gate isolation insulator includes a first gate isolation insulating layer embedded in a gate isolation space resulting from cutting the at least one gate line, the first gate isolation insulating layer protruding above a top surface of the at least one gate line in a vertical direction, a second gate isolation insulating layer embedded in a gate recessed hole inwardly recessed from a top surface of the first gate isolation insulating layer, and a third gate isolation insulating layer capping the first gate isolation insulating layer and the second gate isolation insulating layer.

### CROSS-REFERENCE TO RELATED APPLICATION

This application claims priority under 35 U.S.C. § 119 to Korean Patent Application No. 10-2023-0195356, filed on Dec. 28, 2023, in the Korean Intellectual Property Office, the disclosure of which is incorporated by reference herein in its entirety.

### BACKGROUND

With the rapid development of down-scaling of integrated circuit devices, it is necessary to secure the accuracy of the operations of integrated circuit devices as well as the fast operating speed thereof. Accordingly, there has been various research into providing an integrated circuit device having a structure capable of providing optimal performance and increasing reliability.

### SUMMARY

In general, in some aspects, the present disclosure is directed toward an integrated circuit device, including an integrated circuit device having fin type active regions and gate lines, that has a structure capable of increasing the reliability of elements in a device region having a reduced area due to down-scaling.

According to some aspects, the present disclosure is directed to an integrated circuit device includes a plurality of fin-type active regions extending lengthwise on a substrate in a first horizontal direction and apart from each other in a second horizontal direction that is perpendicular to the first horizontal direction, a plurality of gate lines on the plurality of fin-type active regions and the substrate, the plurality of gate lines extending lengthwise in the second horizontal direction and being apart from each other in the first horizontal direction, and a gate isolation insulator between the plurality of fin-type active regions, the gate isolation insulator cutting and separating in the second horizontal direction at least one gate line among the plurality of gate lines.

According to some aspects, the present disclosure is directed to a gate isolation insulator that includes a first gate isolation insulating layer embedded in a gate isolation space resulting from cutting the at least one gate line, the first gate isolation insulating layer protruding above a top surface of the at least one gate line in a vertical direction, a second gate isolation insulating layer embedded in a gate recessed hole inwardly recessed from a top surface of the first gate isolation insulating layer, and a third gate isolation insulating layer capping the first gate isolation insulating layer and the second gate isolation insulating layer.

According to some aspects, the present disclosure is directed to an integrated circuit device that includes a plurality of fin-type active regions extending lengthwise on a substrate in a first horizontal direction and apart from each other in a second horizontal direction that is perpendicular to the first horizontal direction, a plurality of nanosheet stacks on the plurality of fin-type active regions and apart from each other in the first horizontal direction and the second horizontal direction, a plurality of gate lines on the plurality of fin-type active regions and the substrate, the plurality of gate lines surrounding the plurality of nanosheet stacks, extending lengthwise in the second horizontal direction, and being apart from each other in the first horizontal direction, and a gate isolation insulator between the plurality of fin-type active regions and between the plurality of nanosheet stacks, the gate isolation insulator cutting and separating in the second horizontal direction at least one gate line among the plurality of gate lines.

According to some aspects, the present disclosure is directed to a gate isolation insulator that includes a first gate isolation insulating layer embedded in a gate isolation space resulting from the cutting of the at least one gate line, the first gate isolation insulating layer protruding above a top surface of the at least one gate line in a vertical direction, a second gate isolation insulating layer embedded in a gate recessed hole inwardly recessed from a top surface of the first gate isolation insulating layer, and a third gate isolation insulating layer capping the first gate isolation insulating layer and the second gate isolation insulating layer.

According to some aspects, the present disclosure is directed to an integrated circuit device that includes a plurality of fin-type active regions extending lengthwise on a substrate in a first horizontal direction and apart from each other in a second horizontal direction that is perpendicular to the first horizontal direction, a plurality of nanosheet stacks on the plurality of fin-type active regions and apart from each other in the first horizontal direction and the second horizontal direction, a plurality of gate lines on the plurality of fin-type active regions and the substrate, the plurality of gate lines surrounding the plurality of nanosheet stacks, extending lengthwise in the second horizontal direction, and being apart from each other in the first horizontal direction, and a gate isolation insulator between the plurality of fin-type active regions and between the plurality of nanosheet stacks, the gate isolation insulator cutting and separating in the second horizontal direction at least one gate line among the plurality of gate lines.

According to some aspects, the present disclosure is directed to a gate isolation insulator that includes a gate liner insulating layer on an inner wall and a bottom of a gate isolation space resulting from the cutting of the at least one gate line, a first gate isolation insulating layer on the gate liner insulating layer and embedded in the gate isolation space, the first gate isolation insulating layer protruding above a top surface of the at least one gate line in a vertical direction, a second gate isolation insulating layer embedded in a gate recessed hole inwardly recessed from a top surface of the first gate isolation insulating layer, the gate recessed hole being apart from an inner sidewall of the gate isolation space, and a third gate isolation insulating layer capping the gate liner insulating layer, the first gate isolation insulating layer and the second gate isolation insulating layer and extending in the second horizontal direction.

### BRIEF DESCRIPTION OF THE DRAWINGS

Example implementation will be more clearly understood from the following detailed description, taken in conjunction with the accompanying drawings.

FIG. 1 is plan layout diagram illustrating a partial configuration of an example of an integrated circuit device according to some implementations.

FIG. 2 is a cross-sectional view taken along line Y1-Y1′ in FIG. 1 according to some implementations.

FIG. 3 is an enlarged cross-sectional view of an example of a region EX1 in FIG. 2 according to some implementations.

FIG. 4 is a cross-sectional view taken along line X1-X1′ in FIG. 1 according to some implementations.

FIG. 5 is an enlarged cross-sectional view of an example of a region EX2 in FIG. 4 according to some implementations.

FIGS. 6 to 11 are cross-sectional views illustrating an example of a method of manufacturing an integrated circuit device according to some implementations.

FIGS. 12 to 18 are cross-sectional views illustrating an example of a method of manufacturing an integrated circuit device according to some implementations.

### DETAILED DESCRIPTION

Hereinafter, example implementations will be explained with reference to the accompanying drawings. In the drawings, like reference characters denote like elements, and redundant descriptions thereof will be omitted.

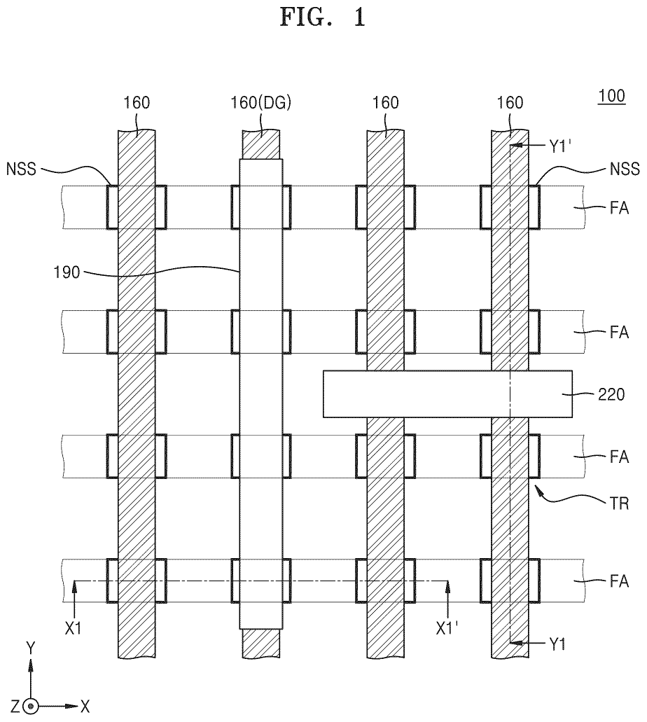

FIG. 1 is plan layout diagram illustrating a partial configuration of an example of an integrated circuit device according to some implementations. In FIG. 1, an integrated circuit device 100 may include a plurality of fin-type active regions FA, a plurality of nanosheet stacks NSS, a plurality of gate lines 160, a gate isolation insulator 220, and a fin isolation insulator 190.

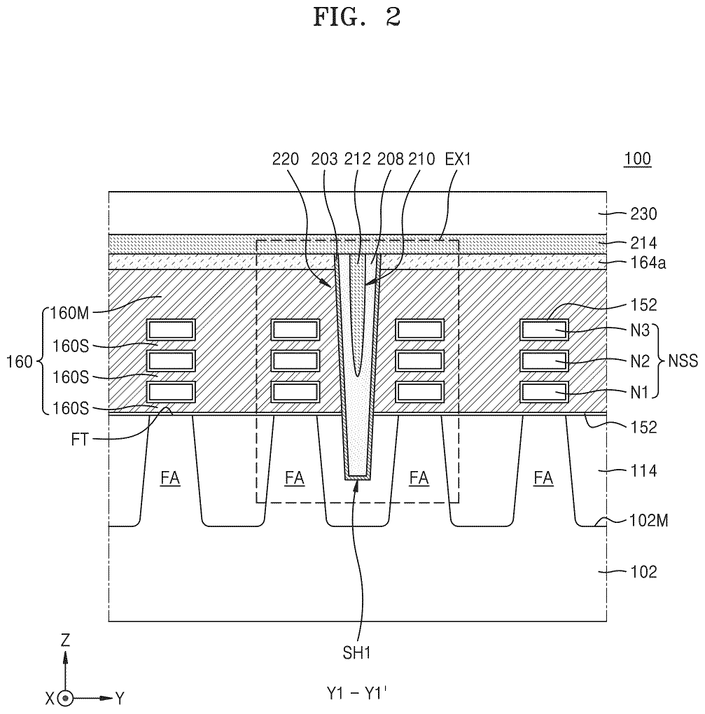

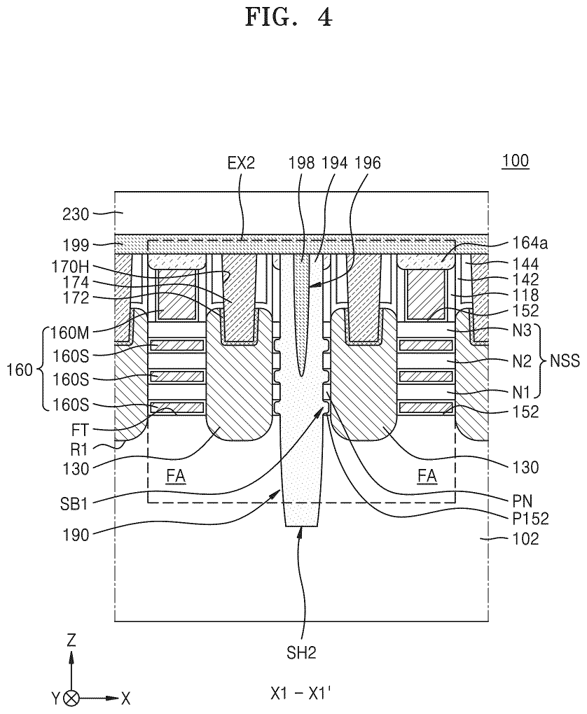

The fin-type active regions FA may be on a substrate (102 in FIGS. 2 and 4) and extend lengthwise in a first horizontal direction (the X direction). The fin-type active regions FA may extend in the first horizontal direction (the X direction) in parallel with each other. The fin-type active regions FA may be apart from each other in a second horizontal direction (the Y direction) that is perpendicular to the first horizontal direction (the X direction). The fin-type active regions FA may be apart from each other in a second horizontal direction (the Y direction) that crosses the first horizontal direction (the X direction).

The nanosheet stacks NSS may be arranged on the fin-type active regions FA. The nanosheet stacks NSS may be respectively at intersections between the fin-type active regions FA and the gate lines 160. The nanosheet stacks NSS may be apart from each other in the first horizontal direction (the X direction) and the second horizontal direction (the Y direction).

The gate lines 160 may extend lengthwise in the second horizontal direction (the Y direction) above the fin-type active regions FA. The gate lines 160 may be apart from each other in the first horizontal direction (the X direction). As described below, the gate lines 160 may be configured to surround the nanosheet stacks NSS. Accordingly, the integrated circuit device 100 may include a field-effect transistor TR having a gate-all-around, which includes a gate (or a gate electrode) surrounding nanosheet stacks. The field-effect transistor TR may form a logic circuit or a memory device.

The gate isolation insulator 220 may be between fin-type active regions FA and between nanosheet stacks NSS and may cut and separate at least one gate line 160 among the gate lines 160 in the second horizontal direction (the Y direction).

In other words, the gate isolation insulator 220 may disconnect at least one gate line 160 in the second horizontal direction (the Y direction). For example, when the gate isolation insulator 220 cuts two gate lines 160, the gate isolation insulator 220 may extend in the first horizontal direction (the X direction). The vertical structure of the gate isolation insulator 220 is described in detail below.

The fin isolation insulator 190 may cut and separate each of the fin-type active regions FA in the first horizontal direction (the X direction). The fin isolation insulator 190 may disconnect each of the fin-type active regions FA in the first horizontal direction (the X direction). Each of the fin-type active regions FA may be separated by the fin isolation insulator 190 and arranged in line in the first horizontal direction (the X direction).

The fin isolation insulator 190 may extend lengthwise in the second horizontal direction (the Y direction) between gate lines 160. The fin isolation insulator 190 may have a planar structure having a line shape extending in the second horizontal direction (the Y direction).

Accordingly, the gate lines 160 may include a plurality of dummy gate lines DG. Each of the dummy gate lines DG may be in a straight line with the fin isolation insulator 190 in the second horizontal direction (the Y direction) and may extend from an end of the fin isolation insulator 190 in the second horizontal direction (the Y direction). The vertical structure of the fin isolation insulator 190 is described in detail below.

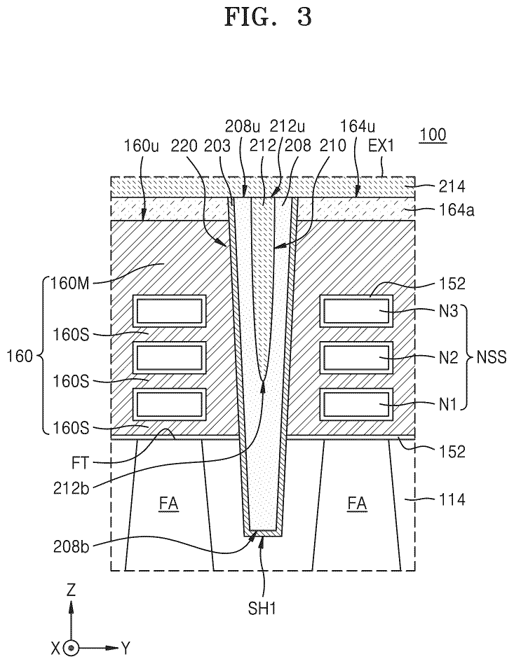

FIG. 2 is a cross-sectional view taken along line Y1-Y1′ in FIG. 1 according to some implementations. FIG. 3 is an enlarged cross-sectional view of an example of a region EX1 in FIG. 2 according to some implementations.

In FIGS. 2 and 3, the integrated circuit device 100 may be implemented in a substrate 102. The substrate 102 may have a main surface 102 extending in a horizontal direction (the XY-plane direction). The substrate 102 may include a semiconductor, such as Si or Ge, or a compound semiconductor, such as SiGe, SiC, GaAs, InAs, InGaAs, or InP.

Each of the terms “SiGe”, “SiC”, “GaAs”, “InAs”, “InGaAs”, and “InP” used herein indicates a material composed of elements included in each term and is not a chemical equation representing stoichiometric relationships. The substrate 102 may include a conductive region, e.g., an impurity-doped well or an impurity-doped structure.

The integrated circuit device 100 may include a plurality of fin-type active regions FA protruding from the substrate 102 in the vertical direction (the Z direction. The fin-type active regions FA may be apart from each other in the second horizontal direction (the Y direction).

A device isolation layer 114 may be between the fin-type active regions FA. The device isolation layer 114 may cover opposite sidewalls of each of the fin-type active regions FA. The fin-type active regions FA may protrude above the substrate 102 in a fin shape. The device isolation layer 114 may include an oxide layer, a nitride layer, or a combination thereof.

The integrated circuit device 100 may include a plurality of nanosheet stacks NSS apart from each other above the substrate 102. The nanosheet stacks NSS may be apart from each other in the second horizontal direction (the Y direction). Each of the nanosheet stacks NSS may include a plurality of nanosheets (e.g., first to third nanosheets N1, N2, and N3), which face a fin top FT of one of the fin-type active regions FA at a position separated in the vertical direction (the Z direction) from the fin top FT of the fin-type active region FA. The nanosheets (e.g., N1, N2, and N3) may include a silicon layer. Each of the nanosheet stacks NSS may include a plurality of nanosheets. In the present embodiment, only three nanosheets (e.g., N1, N2, and N3) are illustrated for convenience of description.

Each of the nanosheet stacks NSS may include the first nanosheet N1, the second nanosheet N2, and the third nanosheet N3, which overlap each other above the fin-type active region FA in the vertical direction (the Z direction). The first nanosheet N1, the second nanosheet N2, and the third nanosheet N3 may respectively have different vertical distances (Z-direction distances) from the fin top FT of the fin-type active region FA.

The first nanosheet N1, the second nanosheet N2, and the third nanosheet N3 included in each of the nanosheet stacks NSS may each function as a channel region. In some implementations, each of the first nanosheet N1, the second nanosheet N2, and the third nanosheet N3 may have, but not limited to, a thickness selected from a range from about 4 nm to about 6 nm.

At this time, the thickness of each of the first nanosheet N1, the second nanosheet N2, and the third nanosheet N3 refers to a size in the vertical direction (the Z direction). In some implementations, the first nanosheet N1, the second nanosheet N2, and the third nanosheet N3 may have substantially the same thicknesses in the vertical direction (the Z direction). In some embodiments, at least some of the first nanosheet N1, the second nanosheet N2, and the third nanosheet N3 may have different thicknesses in the vertical direction (the Z direction).

The first nanosheet N1, the second nanosheet N2, and the third nanosheet N3 included in each of the nanosheet stacks NSS may have the same or similar sizes in the second horizontal direction (the Y direction). In some implementations, unlike FIGS. 2 and 3, at least some of the first nanosheet N1, the second nanosheet N2, and the third nanosheet N3 included in each of the nanosheet stacks NSS may have different sizes in the second horizontal direction (the Y direction).

The integrated circuit device 100 may include gate lines 160. The gate lines 160 may be above the fin-type active regions FA and may surround the first nanosheet N1, the second nanosheet N2, and the third nanosheet N3 and extend lengthwise in the second horizontal direction (the Y direction).

Each of the gate lines 160 may include a main gate portion 160M and a plurality of sub gate portions 160S. The main gate portion 160M may extend lengthwise in the second horizontal direction (the Y direction) to cover the top surfaces of a plurality nanosheet stacks NSS. The sub gate portions 160S may be integrally connected to the main gate portion 160M and respectively between the third nanosheet N3 and the second nanosheet N2, between the second nanosheet N2 and the first nanosheet N1, and between the first nanosheet N1 and each of the fin-type active regions FA. In the vertical direction (the Z direction), the thickness of each of the sub gate portions 160S may be less than the thickness of the main gate portion 160M.

Each of the gate lines 160 may include metal, metal nitride, metal carbide, or a combination thereof. The metal may be selected from Ti, W, Ru, Nb, Mo, Hf, Ni, Co, Pt, Yb, Tb, Dy, Er, and Pd. The metal nitride may be selected from TiN and TaN. The metal carbide may include TiAIC. However, the material of the gate lines 160 is not limited to those described above.

The integrated circuit device 100 may include a gate dielectric layer 152. The gate dielectric layer 152 may be between a nanosheet stack NSS and a gate line 160. In some implementations, the gate dielectric layer 152 may include a stack structure of an interface dielectric layer and a high-k dielectric layer. The interface dielectric layer may include a low-k dielectric layer, e.g., a silicon oxide layer, a silicon oxynitride layer, or a combination thereof, having a permittivity of about 9 or less.

In some implementations, the interface dielectric layer may be omitted. The high-k dielectric layer may include a material having a higher dielectric constant than a silicon oxide layer. For example, the high-k dielectric layer may have a dielectric constant of about 10 to about 25. The high-k dielectric layer may include hafnium oxide but is not limited thereto.

The integrated circuit device 100 may include the gate isolation insulator 220. The gate isolation insulator 220 may cut and separate a gate line 160 in the second horizontal direction (the Y direction). The gate isolation insulator 220 may include a gate liner insulating layer 203, a first gate isolation insulating layer 208, a second gate isolation insulating layer 212, and a third gate isolation insulating layer 214.

The gate liner insulating layer 203 may be formed on the inner wall and bottom of a gate isolation space SH1, which cuts the gate line 160 and exposes the substrate 102. The gate liner insulating layer 203 may protrude above a top surface 160u of the gate line 160 in the vertical direction (the Z direction).

In some implementations, the bottom of the gate isolation space SH1 may be in the device isolation layer 114. In some implementations, the gate liner insulating layer 203 may include a silicon nitride layer. In some implementations, the gate liner insulating layer 203 may not be formed.

The first gate isolation insulating layer 208 may be on the gate liner insulating layer 203 and in the gate isolation space SH1. The first gate isolation insulating layer 208 may protrude above the top surface 160u of the gate line 160 in the vertical direction (the Z direction). In some embodiments, the first gate isolation insulating layer 208 may include a silicon oxide layer.

The second gate isolation insulating layer 212 may be embedded in a gate recessed hole 210, which is recessed from a top surface 208u of the first gate isolation insulating layer 208 and is apart from an inner sidewall of the gate isolation space SH1. The gate recessed hole 210 in the gate isolation space SH1 may be apart from the inner sidewall of the gate isolation space SH1. The gate recessed hole 210 may be between gate lines 160. In some embodiments, the second gate isolation insulating layer 212 may include a silicon nitride layer.

In some implementations, the top surface 208u of the first gate isolation insulating layer 208 may be at the same vertical level as a top surface 212u of the second gate isolation insulating layer 212. The term “vertical level” used herein may refer to a distance from the main surface 102M of the substrate 102 in the vertical direction (the Z direction or □Z direction). The top surface 208u of the first gate isolation insulating layer 208 be coplanar with the top surface 212u of the second gate isolation insulating layer 212.

In some implementations, the vertical level of a bottommost surface 208b of the first gate isolation insulating layer 208 may be lower than the vertical level of a bottommost surface 212b of the second gate isolation insulating layer 212. The bottommost surface 208b of the first gate isolation insulating layer 208 may be below the bottommost surface 212b of the second gate isolation insulating layer 212 in the vertical direction (the Z direction).

In some implementations, the vertical level of the bottommost surface 212b of the second gate isolation insulating layer 212 may be lower than the vertical level of the third nanosheet N3 that is at the top among the first to third nanosheets N1, N2, and N3.

The gate liner insulating layer 203, the first gate isolation insulating layer 208, and the second gate isolation insulating layer 212 may be capped with the third gate isolation insulating layer 214. The third gate isolation insulating layer 214 may be above the gate line 160 and extend in the second horizontal direction (the Y direction).

In some implementations, the second gate isolation insulating layer 212 and the third gate isolation insulating layer 214 may be one body (the same body). In some embodiments, the third gate isolation insulating layer 214 may include a silicon nitride layer.

The integrated circuit device 100 may further include a capping insulating pattern 164a. The capping insulating pattern 164a may be on the gate line 160. The capping insulating pattern 164a may be formed to protect the gate line 160. The third gate isolation insulating layer 214 may be on the capping insulating pattern 164a. The top surface 208u of the first gate isolation insulating layer 208 and the top surface 212u of the second gate isolation insulating layer 212 may be at the same vertical level as a top surface 164u of the capping insulating pattern 164a.

The integrated circuit device 100 may include an interlayer insulating layer 230 on the third gate isolation insulating layer 214. The interlayer insulating layer 230 may include a silicon oxide layer. A metal wiring pattern may be formed inside the interlayer insulating layer 230.

The integrated circuit device 100 described above may include the gate isolation insulator 220 that completely fills the gate isolation space SH1 by using the gate liner insulating layer 203 and the first to third gate isolation insulating layers 208, 212, and 214. The integrated circuit device 100 may completely separate the gate line 106 in the second horizontal direction (the Y direction) by using the gate isolation insulator 220.

The integrated circuit device 100 may include the capping insulating pattern 164a on the gate line 160 to protect the gate line 160. Accordingly, the integrated circuit device 100 may increase device reliability (i.e., the reliability of a transistor).

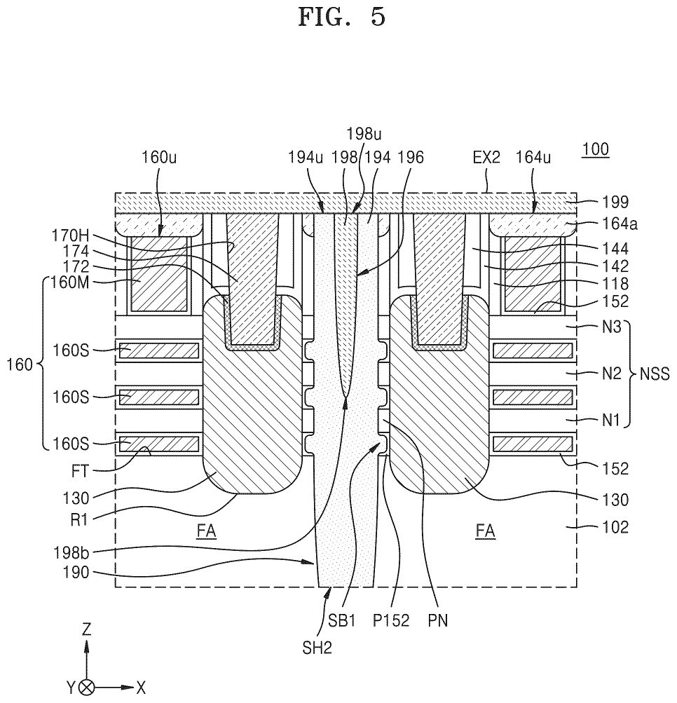

FIG. 4 is a cross-sectional view taken along line X1-X1′ in FIG. 1 according to some implementations. FIG. 5 is an enlarged cross-sectional view of an example of a region EX2 in FIG. 4 according to some implementations.

In FIGS. 2 to 5, like reference numerals denote like elements. Redundant descriptions given above with reference to FIGS. 2 and 3 are brief or omitted below.

The integrated circuit device 100 may include a fin-type active region FA, a plurality of nanosheet stacks NSS, and a plurality of gate lines 160. The gate lines 160 may be on the fin-type active region FA. The nanosheet stacks NSS may be above the fin top FT of the fin-type active region FA. Each of the nanosheet stacks NSS may include first to third nanosheets N1, N2, and N3, which face the fin top FT of the fin-type active region FA.

The first nanosheet N1, the second nanosheet N2, and the third nanosheet N3 may each function as a channel region. The first nanosheet N1, the second nanosheet N2, and the third nanosheet N3 may have the same or similar sizes in the first horizontal direction (the X direction). In some embodiments, at least some of the first nanosheet N1, the second nanosheet N2, and the third nanosheet N3 may have different sizes in the first horizontal direction (the X direction).

The gate lines 160 may be arranged above the fin-type active region FA to surround the first nanosheet N1, the second nanosheet N2, and the third nanosheet N3. Each of the gate lines 160 may include a main gate portion 160M and a plurality of sub gate portions 160S.

The main gate portion 160M may be above the top surface of each of the nanosheet stacks NSS. The sub gate portions 160S may be integrally connected to the main gate portion 160M and respectively between the third nanosheet N3 and the second nanosheet N2, between the second nanosheet N2 and the first nanosheet N1, and between the first nanosheet N1 and the fin-type active region FA. In the vertical direction (the Z direction), the thickness of each of the sub gate portions 160S may be less than the thickness of the main gate portion 160M.

The integrated circuit device 100 may include the gate dielectric layer 152. The gate dielectric layer 152 may be between the nanosheet stacks NSS and the gate lines 160. The gate dielectric layer 152 may be between each of the sub gate portions 160S and one of the first nanosheet N1, the second nanosheet N2, and the third nanosheet N3 and between the sub gate portions 160S and a source/drain region 130.

Substrate recesses R1 may be formed in the fin-type active region FA at opposite sides of one of the gate lines 160. The vertical level of the bottommost surface of each of the substrate recesses R1 may be lower than the vertical level than the fin top FT of the fin-type active region FA.

The integrated circuit device 100 may include a plurality of source/drain regions 130. The source/drain regions 130 may be respectively arranged in the substrate recesses R1. Source/drain regions 130 may be on the fin-type active region FA and respectively at opposite sides of one gate line 160.

The source/drain regions 130 may be on the fin-type active region FA and respectively at opposite sides of one nanosheet stack NSS. The source/drain regions 130 may be in contact with the sidewall of the nanosheet stack NSS. Each of the source/drain regions 130 may be in contact with sidewalls of the first nanosheet N1, the second nanosheet N2, and the third nanosheet N3, which are included in the nanosheet stack NSS.

Opposite sidewalls of each of the sub gate portions 160S of the gate line 160 may be separated from the source/drain regions 130 by the gate dielectric layer 152. In some implementations, the field-effect transistor TR in FIG. 1 may include a p-channel metal-oxide semiconductor (PMOS) transistor. The source/drain regions 130 may include a plurality of epitaxially grown SiGe layers. For example, each of the source/drain regions 130 may include an Si₁₋ₓGeₓ layer doped with a p-type dopant, where x>0, and may have an atomic percent of Ge, which increases away from the bottom surface of the substrate recesses R1 in the vertical direction (the Z direction).

The p-type dopant may include, but not limited to, boron (B), gallium (Ga), carbon (C), or a combination thereof. In implementations, each of the source/drain regions 130 may include, but not limited to, an Si₁₋ₓGeₓ layer doped with a p-type dopant, where 0.01<x<0.70.

In some implementations, the field-effect transistor TR in FIG. 1 may include an n-channel MOS (NMOS) transistor. Each of the source/drain regions 130 may include an epitaxially grown Si layer or an epitaxially grown SiC layer. For example, the source/drain regions 130 may include an Si layer doped with an n-type dopant, which may include phosphorous (P) but is not limited thereto.

The integrated circuit device 100 may include an outer insulating spacer 118. Opposite sidewalls of each of the gate lines 160 may be respectively covered with outer insulating spacers 118. The outer insulating spacers 118 may be above the top surface of the nanosheet stack NSS to respectively cover the opposite sidewalls of the main gate portion 160M.

The outer insulating spacers 118 may be separated from the gate line 160 by the gate dielectric layer 152. The outer insulating spacers 118 may include silicon nitride, silicon oxide, SiCN, SiBN, SION, SiOCN, SiBCN, SiOC, or a combination thereof.

The integrated circuit device 100 may include a capping insulating pattern 164a. The top surface of each of the gate dielectric layer 152, the gate line 160, and the outer insulating spacers 118 is covered with the capping insulating pattern 164a. The capping insulating pattern 164a may be formed to protect the gate dielectric layer 152 and the gate line 160. The capping insulating pattern 164a may include a silicon nitride layer.

The integrated circuit device 100 may include an insulating liner 142 and an intergate insulating layer 144. Each of the outer insulating spacers 118 and the source/drain regions 130 above the substrate 102 may be covered with the insulating liner 142. The insulating liner 142 may include silicon nitride (SiN), silicon oxide (SiO), SiCN, SiBN, SION, SIOCN, SiBCN, SiOC, or a combination thereof. In some embodiments, the insulating liner 142 may be omitted.

The intergate insulating layer 144 may be on the insulating liner 142. The intergate insulating layer 144 may include a silicon nitride layer, a silicon oxide layer, SiON, SiOCN, or a combination thereof. When the insulating liner 142 is omitted, the intergate insulating layer 144 may be in contact with one of the source/drain regions 130.

The integrated circuit device 100 may include a source/drain contact 174 on the source/drain region 130. The source/drain contact 174 may extend lengthwise from the source/drain region 130 away from the substrate 102 in the vertical direction (the Z direction). A metal silicide layer 172 may be between the source/drain region 130 and the source/drain contact 174.

The source/drain contact 174 may fill a contact hole 170H, which penetrates the intergate insulating layer 144 and the insulating liner 142 in the vertical direction (the Z direction) and extends into the source/drain region 130. The source/drain region 130 may be separated from the source/drain contact 174 by the metal silicide layer 172.

In some implementations, the source/drain contact 174 may include metal, conductive metal nitride, or a combination thereof. For example, the source/drain contact 174 may include W, Cu, Al, Ti, Ta, TiN, TaN, an alloy thereof, or a combination thereof. In some embodiments, the metal silicide layer 172 may include titanium silicide but is not limited thereto. In some implementations, the metal silicide layer 172 may be omitted.

The integrated circuit device 100 may include the fin isolation insulator 190. The fin isolation insulator 190 may be between source/drain regions 130 and may cut the fin-type active region FA. The fin isolation insulator 190 may cut and separate the fin-type active region FA in the first horizontal direction (the X direction). The vertical level of the topmost surface of the fin isolation insulator 190 may be higher than the vertical level of the topmost surface of the source/drain regions 130.

The fin isolation insulator 190 may include a first fin isolation insulating layer 194, a second fin isolation insulating layer 198, and a third fin isolation insulating layer 199. The first fin isolation insulating layer 194 may be embedded in a fin isolation space SH2, which cuts the fin-type active region FA and exposes the substrate 102.

As described below, the fin isolation space SH2 may come in contact with a nanosheet piece PN, a dielectric layer piece P152, and a ribbed surface SB1 during manufacturing processes. The first fin isolation insulating layer 194 may fill the fin isolation space SH2 to be in contact with nanosheet piece PN, the dielectric layer piece P152, and the ribbed surface SB1.

The first fin isolation insulating layer 194 may protrude above the top surface 160u of the gate line 160 in the vertical direction (the Z direction). In some implementations, the bottom of the fin isolation space SH2 may be below the bottom of the fin-type active region FA. In some embodiments, the first fin isolation insulating layer 194 may include a silicon oxide layer.

The second fin isolation insulating layer 198 may be embedded in a fin recessed hole 196, which is recessed from a top surface 194u of the first fin isolation insulating layer 194 and is apart from an inner sidewall of the fin isolation space SH2. The fin recessed hole 196 in the fin isolation space SH2 may be apart from the inner sidewall of the fin isolation space SH2. The fin recessed hole 196 may be between source/drain regions 130. In some embodiments, the second fin isolation insulating layer 198 may include a silicon nitride layer.

In some implementations, the top surface 194u of the first fin isolation insulating layer 194 may be at the same vertical level as a top surface 198u of the second fin isolation insulating layer 198. In some implementations, the vertical level of a bottommost surface 198b of the second fin isolation insulating layer 198 may be lower than the vertical level of the third nanosheet N3 that is at the top among the first to third nanosheets N1, N2, and N3.

The first fin isolation insulating layer 194 and the second fin isolation insulating layer 198 may be capped with the third fin isolation insulating layer 199. The third fin isolation insulating layer 199 may be above gate lines 160 and extend in the first horizontal direction (the X direction).

In some implementations, the second fin isolation insulating layer 198 and the third fin isolation insulating layer 199 may be one body (the same body). In some implementations, the third fin isolation insulating layer 199 may include a silicon nitride layer.

The third fin isolation insulating layer 199 may be on the capping insulating pattern 164a. The top surface 194u of the first fin isolation insulating layer 194 and the top surface 198u of the second fin isolation insulating layer 198 may be at the same vertical level as the top surface 164u of the capping insulating pattern 164a.

The integrated circuit device 100 may include the interlayer insulating layer 230 on the third fin isolation insulating layer 199. The interlayer insulating layer 230 may include a silicon oxide layer. A metal wiring pattern may be formed inside the interlayer insulating layer 230.

The integrated circuit device 100 described above may include the fin isolation insulator 190 that completely fills the fin isolation space SH2 by using the first to third fin isolation insulating layers 194, 198, and 199. The integrated circuit device 100 may completely separate the fin-type active region FA in the first horizontal direction (the X direction) by using the fin isolation insulator 190.

The integrated circuit device 100 may include the capping insulating pattern 164a on the gate line 160 to protect the gate line 160. Accordingly, the integrated circuit device 100 may increase device reliability (i.e., the reliability of a transistor).

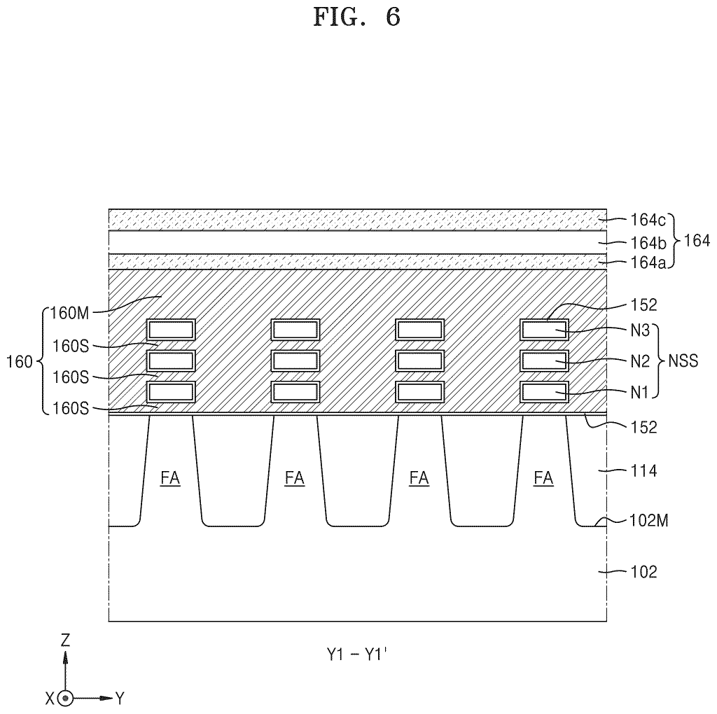

FIGS. 6 to 11 are cross-sectional views illustrating an example of a method of manufacturing an integrated circuit device according to some implementations. In FIGS. 6 to 11, a method of manufacturing elements of a part may correspond to the cross-section taken along line Y1-Y1′ in FIG. 1. FIGS. 6 to 11 illustrate an example of a method of manufacturing the integrated circuit device 100 of FIGS. 2 and 3. In FIGS. 1 to 3 and 6 to 11, like reference numerals denote like elements. Redundant descriptions given above with reference to FIGS. 1 to 3 are brief or omitted below.

In FIG. 6, fin-type active regions FA and the device isolation layer 114 may be formed in the substrate 120. The fin-type active regions FA may be formed by forming trenches to be apart from each other in the substrate 102 and forming the device isolation layer 114 in the trenches. The fin-type active regions FA may be formed to protrude above the main surface 102M of the substrate 102 in the vertical direction (the Z direction).

A plurality of nanosheet stacks NSS may be respectively formed above the fin-type active regions FA. Each of the nanosheet stacks NSS may include the first nanosheet N1, the second nanosheet N2, and the third nanosheet N3. The gate dielectric layer 152 may be formed to cover the top surfaces of the fin-type active regions FA and the device isolation layer 114 and surround the first nanosheet N1, the second nanosheet N2, and the third nanosheet N3.

Continuously, a gate line 160 may be formed above the fin-type active regions FA and the device isolation layer 114 to surround the nanosheet stacks NSS. The gate line 160 may include the main gate portion 160M and the sub gate portions 160S. In some embodiments, the gate line 160 may be formed by a replacement gate process.

The main gate portion 160M may extend lengthwise in the second horizontal direction (the Y direction) and cover the top surfaces of the nanosheet stacks NSS. The sub gate portions 160S may be integrally connected to the main gate portion 160M and respectively between the third nanosheet N3 and the second nanosheet N2, between the second nanosheet N2 and the first nanosheet N1, and between the first nanosheet N1 and each of the fin-type active regions FA. In the vertical direction (the Z direction), the thickness of each of the sub gate portions 160S may be less than the thickness of the main gate portion 160M.

A plurality of capping insulating patterns 164 may be formed on the gate line 160. The capping insulating patterns 164 may include a first capping insulating pattern 164a, a second capping insulating pattern 164b, and a third capping insulating pattern 164c. In some implementations, the first capping insulating pattern 164a and the third capping insulating pattern 164c may each include a silicon nitride layer. The second capping insulating pattern 164b may include a silicon oxide layer.

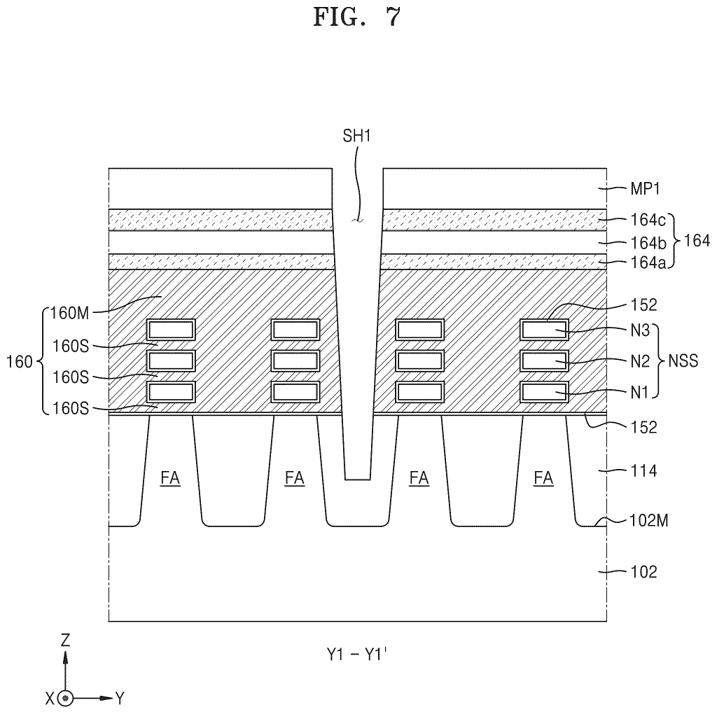

In FIG. 7, a gate mask pattern MP1 for gate isolation may be formed on the capping insulating patterns 164. A gate isolation space SH1 exposing the device isolation layer 114 may be formed by etching the capping insulating patterns 164 and the gate line 160 by using the gate mask pattern MP1 as an etch mask.

The gate isolation space SH1 may be formed by etching the capping insulating patterns 164, the main gate portion 160M of the gate line 160, the gate dielectric layer 152 on the device isolation layer 114, and a portion of the device isolation layer 114 by using the gate mask pattern MP1 as an etch mask. In some implementations, the gate isolation space SH1 may expose the main surface 102M of the substrate 102 by further etching the device isolation layer 114.

The gate isolation space SH1 may be formed between nanosheet stacks NSS. The gate isolation space SH1 may cut and separate the gate line 160 in the second horizontal direction (the Y direction).

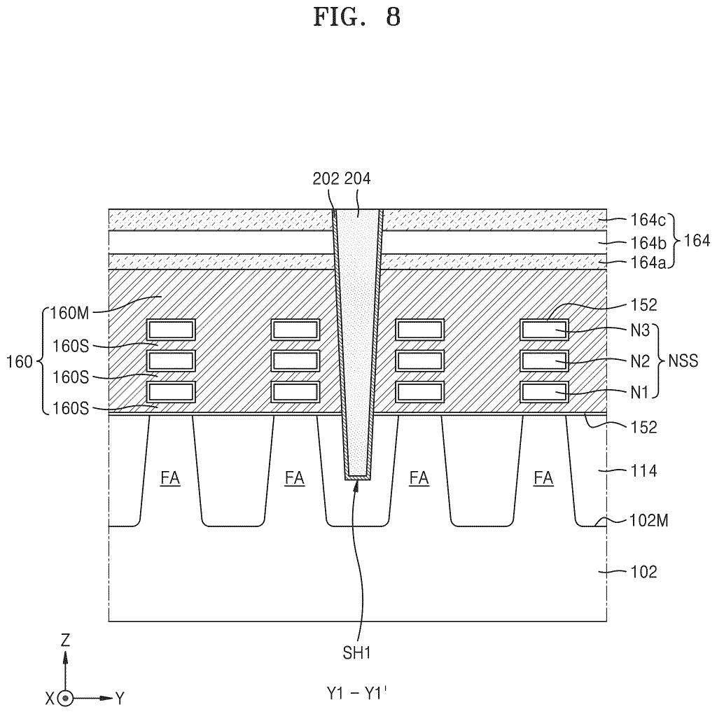

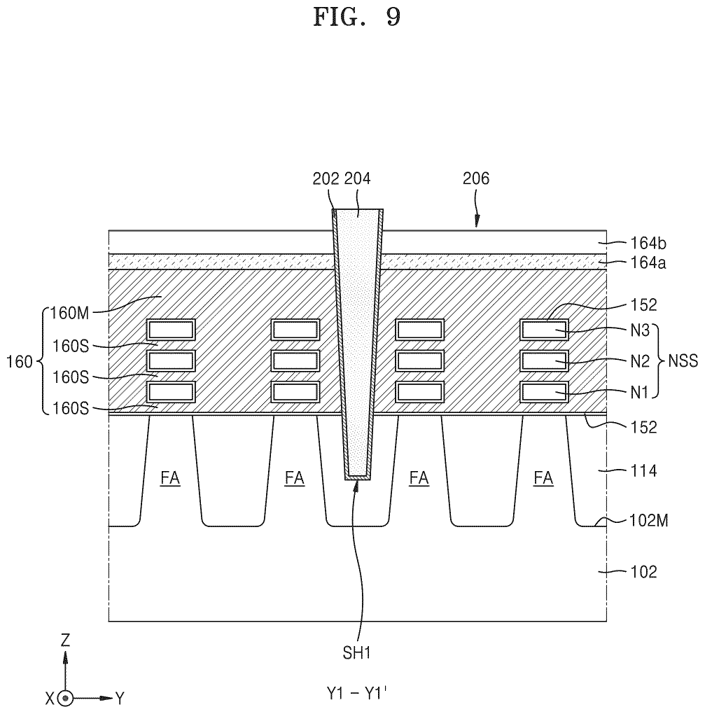

In FIGS. 8 and 9, after the gate mask pattern MP1 is removed, as shown in FIG. 8, a gate liner insulting material layer 202 may be formed on the inner wall and bottom of the gate isolation space SH1. The gate liner insulting material layer 202 may include a silicon nitride layer. A first gate isolation insulating material layer 204 may be formed on the gate liner insulting material layer 202 to fill the gate isolation space SH1. The first gate isolation insulating material layer 204 may include a silicon oxide layer.

In FIG. 9, the third capping insulating pattern 164c may be etched back and removed. As a result, a step 206 may be formed between the top surface of each of the gate liner insulting material layer 202 and the first gate isolation insulating material layer 204 and the top surface of the second capping insulating pattern 164b.

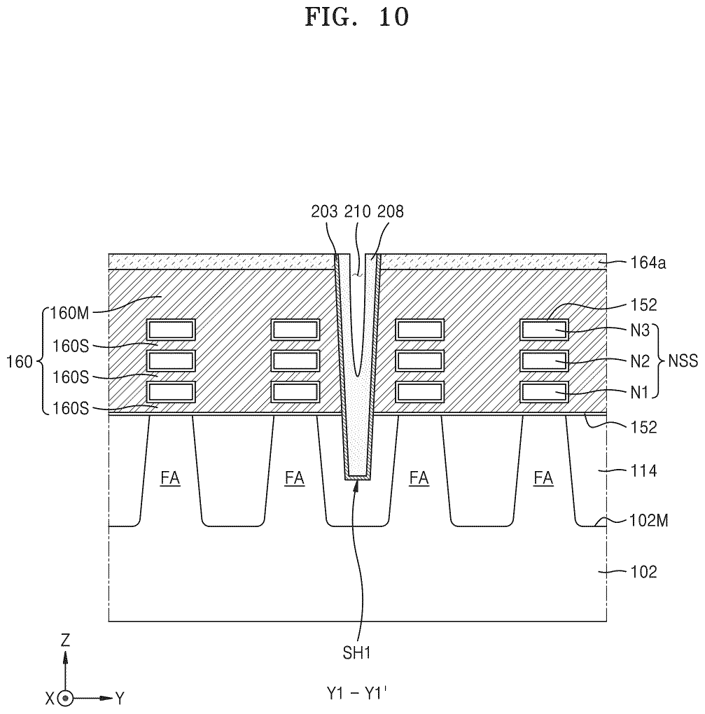

In FIG. 10, the second capping insulating pattern 164b and upper portions of the gate liner insulting material layer 202 and the first gate isolation insulating material layer 204 may be primarily removed by chemical mechanical polishing (CMP). The primary CMP may be performed on the second capping insulating pattern 164b and the upper portions of the gate liner insulting material layer 202 and the first gate isolation insulating material layer 204 by using the top surface of the first capping insulating pattern 164a as a polishing stop point. After the primary CMP, the resultant structure may be cleaned.

In this way, the first capping insulating pattern 164a may protect the gate line 160 from being damaged during the primary CMP. During the primary CMP, the first capping insulating pattern 164a may remain on the gate line 160. The gate liner insulating layer 203 may be formed on the inner wall and bottom of the gate isolation space SH1. The first gate isolation insulating layer 208 may be formed on the gate liner insulating layer 203 in the gate isolation space SH1.

Furthermore, as shown in FIG. 10, the gate recessed hole 210 may be formed in the first gate isolation insulating layer 208 after the primary CMP or the cleaning of the resultant structure. The gate recessed hole 210 may be inwardly recessed from the top surface (or the surface) of the first gate isolation insulating layer 208. The gate recessed hole 210 may be formed to be apart from the inner sidewall of the gate isolation space SH1.

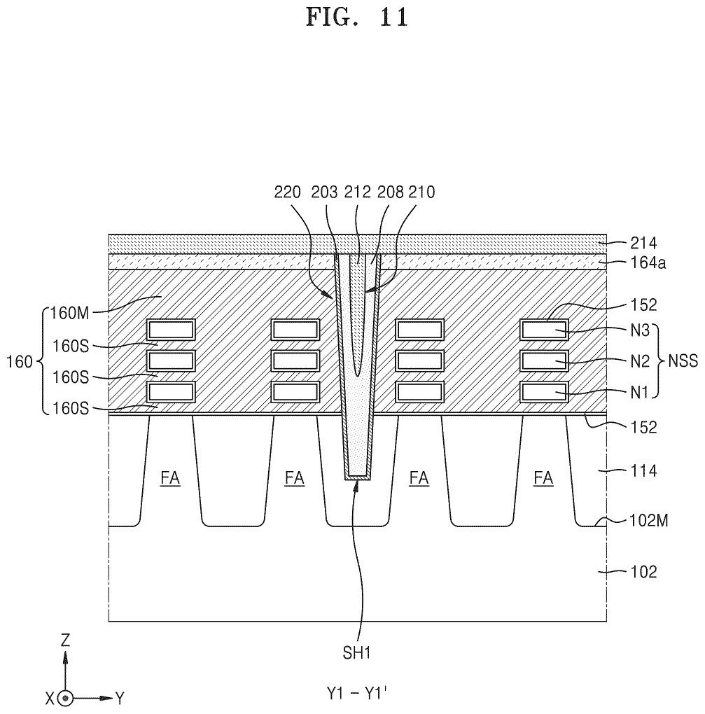

In FIG. 11, the second gate isolation insulating layer 212 may be formed to fill the gate recessed hole 210. The third gate isolation insulating layer 214 may be formed on the first gate isolation insulating layer 208, the second gate isolation insulating layer 212, and the first capping insulating pattern 164a.

The third gate isolation insulating layer 214 may be formed by forming a third gate isolation insulating material layer on the second gate isolation insulating layer 212 and the first capping insulating pattern 164a and then performing secondary CMP on the third gate isolation insulating material layer.

The second gate isolation insulating layer 212 and the third gate isolation insulating layer 214 may be formed using the same material in a single process. The second gate isolation insulating layer 212 and the third gate isolation insulating layer 214 may include a silicon nitride layer.

Through the manufacturing processes described above, the gate isolation insulator 220 including the gate liner insulating layer 203, the first gate isolation insulating layer 208, the second gate isolation insulating layer 212, and the third gate isolation insulating layer 214 may be formed. Subsequently, the integrated circuit device 100 may be manufactured by forming the interlayer insulating layer 230 on the third gate isolation insulating layer 214, as shown in FIG. 2.

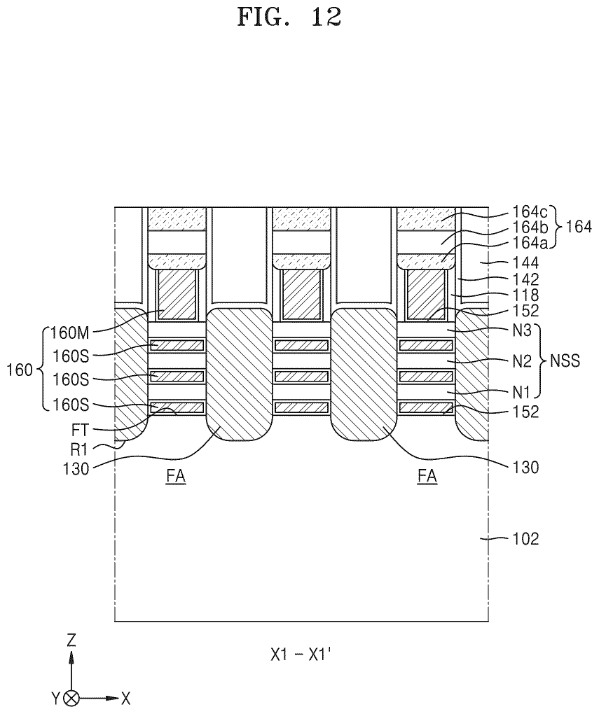

FIGS. 12 to 18 are cross-sectional views illustrating an example of a method of manufacturing an integrated circuit device according to some implementations.

In FIGS. 12 to 18, a method of manufacturing elements of a part may correspond to the cross-section taken along line X1-X1′ in FIG. 1. FIGS. 12 to 18 illustrate an example of a method of manufacturing the integrated circuit device 100 of FIGS. 4 and 5.

In FIGS. 1, 4, 5, and 12 to 18, like reference numerals denote like elements. Redundant descriptions given above with reference to FIGS. 1, 4, and 5 are brief or omitted below.

In FIG. 12, a fin-type active region FA may be formed in the substrate 120. A plurality of nanosheet stacks NSS may be formed above the fin-type active region FA. Each of the nanosheet stacks NSS may include the first nanosheet N1, the second nanosheet N2, and the third nanosheet N3.

Substrate recesses R1 may be formed in an upper portion of the fin-type active region FA to be between the nanosheet stacks NSS. The vertical level of the bottommost surface of each of the substrate recesses R1 may be lower than the vertical level than the fin top FT of the fin-type active region FA. Source/drain regions 130 may be formed in the upper portion of the fin-type active region FA to be between the nanosheet stacks NSS.

The gate dielectric layer 152 may be formed to cover the top surface of the fin-type active region FA and surround the first nanosheet N1, the second nanosheet N2, and the third nanosheet N3. Gate lines 160 may be formed above the fin-type active region FA to surround the nanosheet stacks NSS. Each of the gate lines 160 may include the main gate portion 160M and the sub gate portions 160S. In some implementations, the gate lines 160 may be formed by a replacement gate process.

The main gate portion 160M may be formed on one of the nanosheet stacks NSS. The sub gate portions 160S may be integrally connected to the main gate portion 160M and respectively between the third nanosheet N3 and the second nanosheet N2, between the second nanosheet N2 and the first nanosheet N1, and between the first nanosheet N1 and each of the fin-type active regions FA. In the vertical direction (the Z direction), the thickness of each of the sub gate portions 160S may be less than the thickness of the main gate portion 160M.

An outer insulating spacer 118 may be formed on the gate dielectric layer 152 on a sidewall of the main gate portion 160M. Outer insulating spacers 118 may be above the top surface of each of the nanosheet stacks NSS to respectively cover opposite sidewalls of the main gate portion 160M. The insulating liner 142 may be formed on each of the outer insulating spacers 118 and the source/drain regions 130. The intergate insulating layer 144 may be formed on the insulating liner 142.

A plurality of capping insulating patterns 164 may be formed on each of the gate lines 160. The capping insulating patterns 164 may be formed between intergate insulating layers 144. The capping insulating patterns 164 may include a first capping insulating pattern 164a, a second capping insulating pattern 164b, and a third capping insulating pattern 164c. In some implementations, the first capping insulating pattern 164a and the third capping insulating pattern 164c may each include a silicon nitride layer The second capping insulating pattern 164b may include a silicon oxide layer.

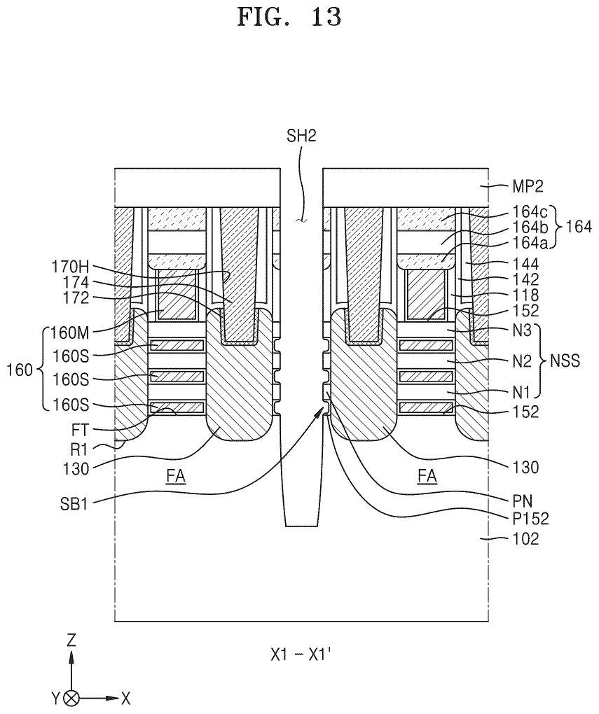

In FIG. 13, source/drain contacts 174 may be respectively formed on the source/drain regions 130. Each of the source/drain contacts 174 may extend lengthwise on one of the source/drain regions 130 in a direction away from the substrate 102 in the vertical direction (the Z direction). A metal silicide layer 172 may be between one of the source/drain regions 130 and one of the source/drain contacts 174.

Each of the source/drain contacts 174 may be formed in a contact hole 170H, which penetrates the intergate insulating layer 144 and the insulating liner 142 and extends into one of the source/drain regions 130 in the vertical direction (the Z direction).

Subsequently, a fin mask pattern MP2 for fin isolation may be formed on the source/drain contacts 174, the intergate insulating layer 144, and the capping insulating patterns 164. In some implementations, the fin mask pattern MP2 may be formed in the same process as the gate mask pattern MP1 described above.

A fin isolation space SH2 exposing the substrate 102 may be formed by etching the capping insulating patterns 164, a nanosheet stack NSS, a gate line 160, and the fin-type active region FA by using the fin mask pattern MP2 as an etch mask. In some implementations, the fin isolation space SH2 may be formed in the same process as the gate isolation space SH1 described above.

While the fin isolation space SH2 is being formed, the sub gate portions 160S exposed by the fin isolation space SH2 and a portion of the gate dielectric layer 152, which covers the sub gate portions 160S, may be removed. As a result, after the fin isolation space SH2 is formed, a plurality of nanosheet pieces PN, which are constituted of respective remaining parts of the first nanosheet N1, the second nanosheet N2, and the third nanosheet N3, and a plurality of dielectric layer pieces P152, which are constituted of remaining parts of the gate dielectric layer 152, may remain in the fin isolation space SH2.

However, structures remaining in the fin isolation space SH2 are not limited to those in FIG. 13. For example, the gate dielectric layer 152 exposed by the fin isolation space SH2 may be entirely removed during the formation of the fin isolation space SH2 such that the source/drain regions 130 may be partially exposed by the fin isolation space SH2.

After the fin isolation space SH2 is formed, a ribbed surface SB1 may be formed in a portion of the inner sidewall of the fin isolation space SH2 due to elements, which are exposed by the fin isolation space SH2 and include various kinds of materials.

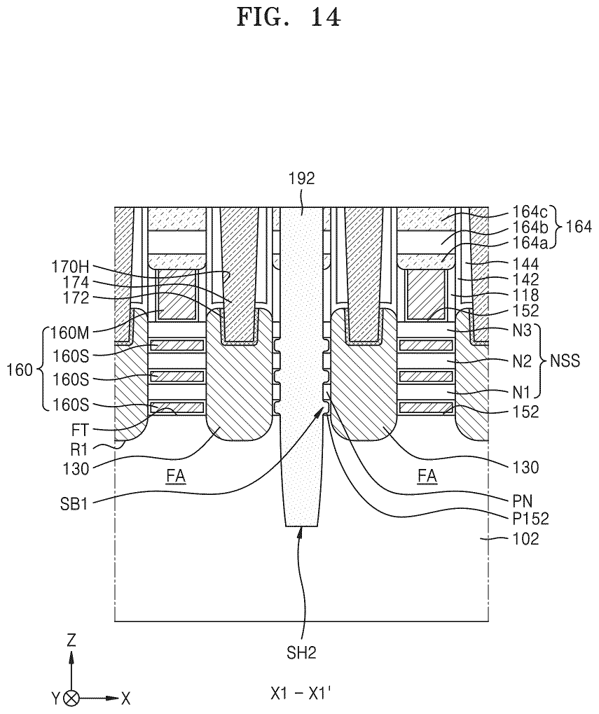

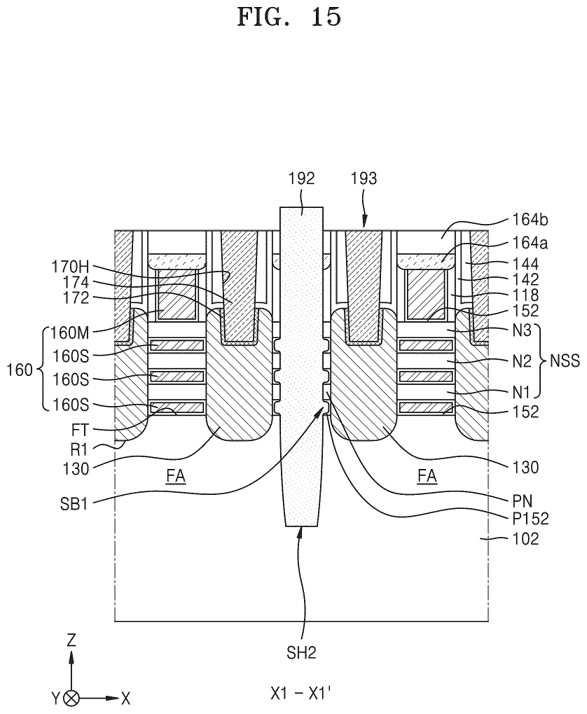

In FIGS. 14 and 15, after the fin mask pattern MP2 is removed as shown in FIG. 14, the fin isolation space SH2 may be filled with a first fin isolation insulating material layer 192. The first fin isolation insulating material layer 192 may include a silicon oxide layer. In some implementations, the first fin isolation insulating material layer 192 may be formed in the same process as the first gate isolation insulating material layer 204 described above.

In FIG. 15, the third capping insulating pattern 164c may be etched back and removed. In this way, a step 193 may be formed between the top surface of the first fin isolation insulating material layer 192 and the top surface of the second capping insulating pattern 164b. When the third capping insulating pattern 164c is etched back, an upper portion of each of the source/drain contacts 174 may also be etched back.

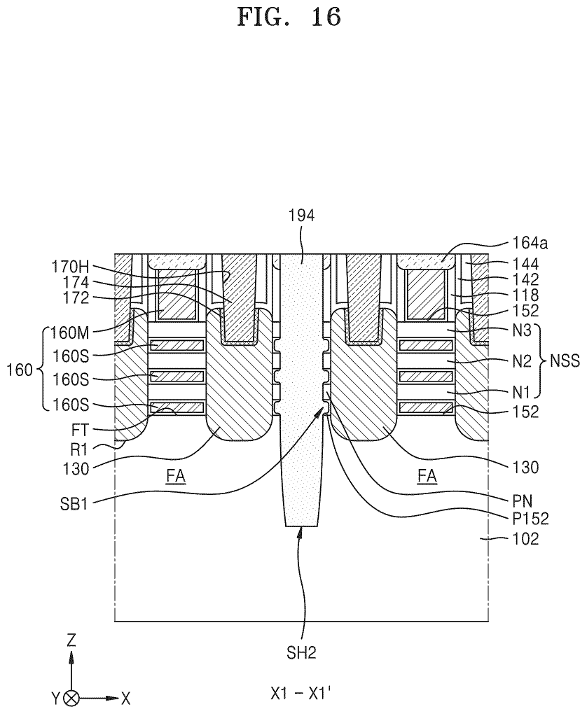

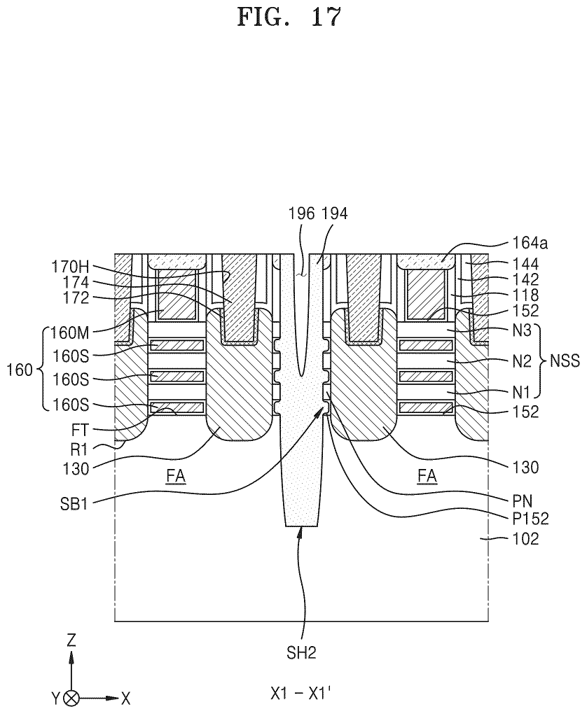

In FIGS. 16 and 17, an upper portion of the first fin isolation insulating material layer 192 (in FIG. 15) and the second capping insulating pattern 164b (in FIG. 15) may be primarily removed by CMP. The primary CMP may be performed on the upper portion of the first fin isolation insulating material layer 192 and the second capping insulating pattern 164b by using the top surface of the first capping insulating pattern 164a as a polishing stop point. While the second capping insulating pattern 164b is polished, the top surfaces of the source/drain contacts 174 may also be etched back. After the primary CMP, the resultant structure may be cleaned.

In this way, the first capping insulating pattern 164a may protect the gate line 160 from being damaged during the primary CMP. During the primary CMP, the first capping insulating pattern 164a may remain on the gate line 160.

The first fin isolation insulating layer 194 may be formed in the fin isolation space SH2. In some implementations, the first fin isolation insulating layer 194 may be formed in the same process as the first gate isolation insulating layer 208 described above.

Furthermore, in FIG. 17, the fin recessed hole 196 may be formed in the first fin isolation insulating layer 194 after the primary CMP or the cleaning of the resultant structure. The fin recessed hole 196 may be inwardly recessed from the top surface (or the surface) of the first fin isolation insulating layer 194. The fin recessed hole 196 may be formed to be apart from the inner sidewall of the fin isolation space SH2.

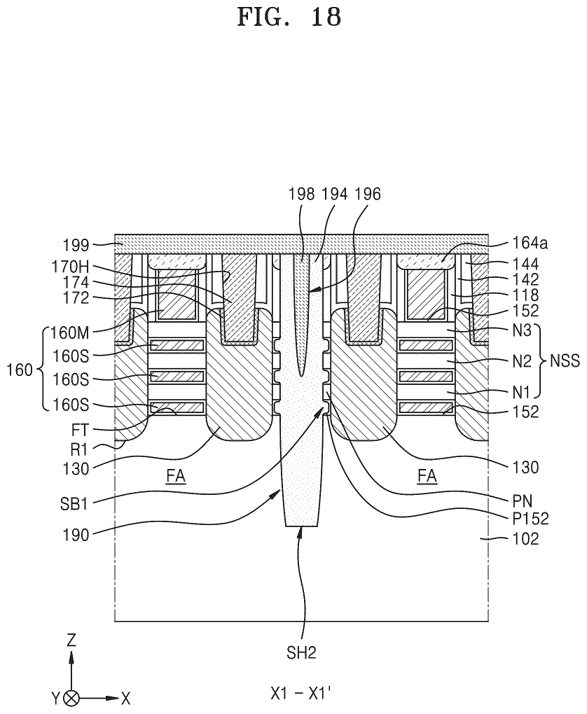

In FIG. 18, the second fin isolation insulating layer 198 may be formed to fill the fin recessed hole 196. In some implementations, the second fin isolation insulating layer 198 may be formed in the same process as the second gate isolation insulating layer 212 described above.

The third fin isolation insulating layer 199 may be formed on the first fin isolation insulating layer 194, the second fin isolation insulating layer 198, the first capping insulating pattern 164a, and the source/drain contacts 174. In some implementations, the third fin isolation insulating layer 199 may be formed in the same process as the third gate isolation insulating layer 214 described above.

The third fin isolation insulating layer 199 may be formed by forming a third fin isolation insulating material layer on the first fin isolation insulating layer 194, the second fin isolation insulating layer 198, the first capping insulating pattern 164a, and the source/drain contacts 174 and then performing secondary CMP on the third fin isolation insulating material layer.

The second fin isolation insulating layer 198 and the third fin isolation insulating layer 199 may be formed using the same material in a single process. The second fin isolation insulating layer 198 and the third fin isolation insulating layer 199 may include a silicon nitride layer.

Through the manufacturing processes described above, the fin isolation insulator 190 including the first fin isolation insulating layer 194, the second fin isolation insulating layer 198, and the third fin isolation insulating layer 199 may be formed. Continuously, as shown in FIG. 4, the integrated circuit device 100 may be manufactured by forming the interlayer insulating layer 230 on the third fin isolation insulating layer 199.

Examples of methods of manufacturing the integrated circuit device 100 of FIGS. 1 to 5 have been described with reference to FIGS. 6 to 11 and FIGS. 12 to 18. The integrated circuit device 100 may be manufactured by making various modifications and changes within the scope of the technical idea of the inventive concept with reference to FIGS. 6 to 11 and FIGS. 12 to 18.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An integrated circuit device comprising:
a plurality of fin-type active regions extending lengthwise on a substrate in a first horizontal direction and apart from each other in a second horizontal direction that is perpendicular to the first horizontal direction;
a plurality of gate lines on the plurality of fin-type active regions and the substrate, the plurality of gate lines extending lengthwise in the second horizontal direction and being apart from each other in the first horizontal direction; and
a gate isolation insulator between the plurality of fin-type active regions, the gate isolation insulator separating, in the second horizontal direction, at least one gate line among the plurality of gate lines,
wherein the gate isolation insulator includes:
a first gate isolation insulating layer embedded in a gate isolation space, the first gate isolation insulating layer protruding above a top surface of the at least one gate line in a vertical direction;
a second gate isolation insulating layer embedded in a gate recessed hole inwardly recessed from a top surface of the first gate isolation insulating layer; and
a third gate isolation insulating layer capping the first gate isolation insulating layer and the second gate isolation insulating layer.

2. The integrated circuit device of claim 1, wherein the second gate isolation insulating layer and the third gate isolation insulating layer are one body.

3. The integrated circuit device of claim 1,
wherein the top surface of the first gate isolation insulating layer is at a same vertical level as a top surface of the second gate isolation insulating layer, and
a vertical level of a bottommost surface of the first gate isolation insulating layer is lower than a vertical level of a bottommost surface of the second gate isolation insulating layer.

4. The integrated circuit device of claim 1, further comprising a capping insulating pattern on the at least one gate line of the plurality of gate lines,
wherein the third gate isolation insulating layer is on the capping insulating pattern, and
the top surface of the first gate isolation insulating layer and a top surface of the second gate isolation insulating layer are at a same vertical level as a top surface of the capping insulating pattern.

5. The integrated circuit device of claim 1, wherein the third gate isolation insulating layer is above the plurality of gate lines and extends in the second direction.

6. The integrated circuit device of claim 1, wherein the gate recessed hole is in the gate isolation space, apart from an inner sidewall of the gate isolation space, and between the plurality of gate lines in the second horizontal direction.

7. The integrated circuit device of claim 1, wherein the gate isolation insulator further includes a gate liner insulating layer on an inner wall and a bottom of the gate isolation space.

8. The integrated circuit device of claim 1,
wherein the first gate isolation insulating layer includes a silicon oxide layer, and
the second gate isolation insulating layer and the third gate isolation insulating layer include a silicon nitride layer.

9. An integrated circuit device comprising:
a plurality of fin-type active regions extending lengthwise on a substrate in a first horizontal direction and apart from each other in a second horizontal direction that is perpendicular to the first horizontal direction;
a plurality of nanosheet stacks on the plurality of fin-type active regions and apart from each other in the first horizontal direction and the second horizontal direction;
a plurality of gate lines on the plurality of fin-type active regions and the substrate, the plurality of gate lines surrounding the plurality of nanosheet stacks, extending lengthwise in the second horizontal direction, and being apart from each other in the first horizontal direction; and
a gate isolation insulator between the plurality of fin-type active regions and between the plurality of nanosheet stacks, the gate isolation insulator separating, in the second horizontal direction, at least one gate line among the plurality of gate lines,
wherein the gate isolation insulator includes:
a first gate isolation insulating layer embedded in a gate isolation space, the first gate isolation insulating layer protruding above a top surface of the at least one gate line in a vertical direction;
a second gate isolation insulating layer embedded in a gate recessed hole inwardly recessed from a top surface of the first gate isolation insulating layer; and
a third gate isolation insulating layer capping the first gate isolation insulating layer and the second gate isolation insulating layer.

10. The integrated circuit device of claim 9,
wherein each of the plurality of nanosheet stacks includes a plurality of nanosheets, and
a vertical level of a bottommost surface of the second gate isolation insulating layer is below a vertical level of a topmost nanosheet among the plurality of nanosheets.

11. The integrated circuit device of claim 9,
wherein the second gate isolation insulating layer and the third gate isolation insulating layer are one body, and
the top surface of the first gate isolation insulating layer is at a same vertical level as a top surface of the second gate isolation insulating layer.

12. The integrated circuit device of claim 9, further comprising a capping insulating pattern on the plurality of gate lines,
wherein the third gate isolation insulating layer is on the capping insulating pattern, and
the top surface of the first gate isolation insulating layer and a top surface of the second gate isolation insulating layer are at a same vertical level as a top surface of the capping insulating pattern.

13. The integrated circuit device of claim 9, wherein the third gate isolation insulating layer is above the plurality of gate lines and extends in the second direction.

14. The integrated circuit device of claim 9, further comprising a fin isolation insulator extending in the second horizontal direction between the plurality of gate lines, and
wherein the fin isolation insulator separates, in the first horizontal direction, the plurality of fin-type active regions.

15. The integrated circuit device of claim 14,
wherein the first gate isolation insulating layer includes a silicon oxide layer,
the second gate isolation insulating layer and the third gate isolation insulating layer include a silicon nitride layer, and
the fin isolation insulator includes a silicon oxide layer.

16. The integrated circuit device of claim 14, further comprising source/drain regions on the plurality of fin-type active regions and at opposite sides of the fin isolation insulator,
wherein a vertical level of a top surface of the fin isolation insulator is higher than a vertical level of top surfaces of the source/drain regions.

17. An integrated circuit device comprising:
a plurality of fin-type active regions extending lengthwise on a substrate in a first horizontal direction and apart from each other in a second horizontal direction that is perpendicular to the first horizontal direction;
a plurality of nanosheet stacks on the plurality of fin-type active regions and apart from each other in the first horizontal direction and the second horizontal direction;
a plurality of gate lines on the plurality of fin-type active regions and the substrate, the plurality of gate lines surrounding the plurality of nanosheet stacks, extending lengthwise in the second horizontal direction, and being apart from each other in the first horizontal direction; and
a gate isolation insulator between the plurality of fin-type active regions and between the plurality of nanosheet stacks, the gate isolation insulator separates, in the second horizontal direction, at least one gate line among the plurality of gate lines,
wherein the gate isolation insulator includes:
a gate liner insulating layer on an inner wall and a bottom of a gate isolation space;
a first gate isolation insulating layer on the gate liner insulating layer and embedded in the gate isolation space, the first gate isolation insulating layer protruding above a top surface of the at least one gate line in a vertical direction;
a second gate isolation insulating layer embedded in a gate recessed hole inwardly recessed from a top surface of the first gate isolation insulating layer, the gate recessed hole being apart from an inner sidewall of the gate isolation space; and
a third gate isolation insulating layer capping the gate liner insulating layer, the first gate isolation insulating layer and the second gate isolation insulating layer and extending in the second horizontal direction.

18. The integrated circuit device of claim 17, further comprising a capping insulating pattern on the at least one gate line,
wherein the third gate isolation insulating layer is on the gate liner insulating layer and the capping insulating pattern, and
the top surface of the first gate isolation insulating layer and a top surface of the second gate isolation insulating layer are at a same vertical level as a top surface of the capping insulating pattern.

19. The integrated circuit device of claim 17, further comprising a fin isolation insulator extending in the second horizontal direction between the plurality of gate lines and separating in the first horizontal direction the plurality of fin-type active regions.

20. The integrated circuit device of claim 19,
wherein the first gate isolation insulating layer includes a silicon oxide layer, the gate liner insulating layer, the second gate isolation insulating layer,
the third gate isolation insulating layer include a silicon nitride layer, and
the fin isolation insulator includes a silicon oxide layer.
